(19) United States
(12) Patent Application Publication
(10) Pub. No.: US 2026/0101572 A1
(43) Pub. Date: Apr. 9, 2026

(54) SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 19/311,682

(22) Filed: Aug. 27, 2025

(30) Foreign Application Priority Data
Oct. 7, 2024 (JP) 2024-176046

(51) Int. Cl. H10D 84/00; H10D 62/832

(52) U.S. Cl. CPC H10D 84/146; H10D 62/8325

(57) ABSTRACT

Provided is a semiconductor device that suppresses a decrease in breakdown resistance of a diode. A semiconductor device includes a semiconductor substrate 20, a transistor 100 provided in the semiconductor substrate and having a gate electrode 12, a first conductivity type source region 6a provided on one side of the gate electrode, and a second conductivity type base contact region 7 provided on the other side of the gate electrode, a diode 200 provided in the semiconductor substrate and adjacent to the transistor on the one side of the gate electrode, and a second conductivity type field relaxation region 8b provided between the transistor and the diode in the semiconductor substrate and having a side face in contact with the main electrode region. A portion of the field relaxation region facing the base contact region protrudes toward the gate electrode in plan view.

### CROSS-REFERENCE TO RELATED APPLICATION

This application claims benefit of priority under 35 USC 119 based on Japanese Patent Application No. 2024-176046 filed on Oct. 7, 2024, the entire contents of which are incorporated by reference herein.

### BACKGROUND OF THE INVENTION

### 1. Field of the Invention

The present disclosure relates to a semiconductor device.

### 2. Description of the Related Art

JP 2023-110951 A disclose a silicon carbide semiconductor device including a trench SBD that includes a Schottky trench between gate trenches adjacent to each other and a conductive film in which the Schottky trench is buried.

JP 2020-113633 A discloses a MOS semiconductor device including an SBD built in the same semiconductor substrate. In the MOS semiconductor device, first trenches constituting a trench gate structure and second trenches constituting a trench side wall SBD are repeatedly arranged in an alternating manner.

In a MOSFET semiconductor device including a built-in SBD, a pn junction is formed at the point where the SBD is connected to the MOSFET. An electric field may concentrate near the pn junction, and this may decrease the reliability.

### SUMMARY OF THE INVENTION

The present disclosure is intended to provide a semiconductor device that suppresses a decrease in breakdown resistance of a diode.

An aspect of the disclosure is a semiconductor device including (a) a semiconductor substrate, (b) a transistor provided in the semiconductor substrate and having a gate electrode, a first conductivity type main electrode region provided on one side of the gate electrode, and a second conductivity type base contact region provided on the other side of the gate electrode, (c) a diode provided in the semiconductor substrate and adjacent to the transistor on the one side of the gate electrode, (d) a second conductivity type field relaxation region provided between the transistor and the diode in the semiconductor substrate and having a side face in contact with the main electrode region, in which (e) a portion of the field relaxation region facing the base contact region protrudes toward the gate electrode in plan view.

### BRIEF DESCRIPTION OF THE DRAWINGS

FIG. 1 is a view schematically illustrating an example planar shape of source regions, base contact regions, and field relaxation regions of a semiconductor device according to a first embodiment;

FIG. 2 is a sectional view illustrating a longitudinal section structure of the semiconductor device, taken along line A-A in FIG. 1;

FIG. 3 is a sectional view illustrating a longitudinal section structure of the semiconductor device, taken along line B-B in FIG. 1;

FIG. 4 is a sectional view illustrating a longitudinal section structure of the semiconductor device, taken along line C-C in FIG. 1;

FIG. 5 is a view schematically illustrating an example planar shape of the source regions, the base contact regions, and the field relaxation regions of the semiconductor device according to the first embodiment;

FIG. 6 is a longitudinal sectional view of a portion with a projection of a field relaxation region in a semiconductor device according to a first alternative embodiment of the first embodiment, in the X direction;

FIG. 7 is a longitudinal sectional view of a portion without the projection of the field relaxation region in the semiconductor device according to the first alternative embodiment of the first embodiment, in the X direction;

FIG. 8 is a longitudinal sectional view of a portion with a p type semiconductor region in the semiconductor device according to the first alternative embodiment of the first embodiment, in the X direction;

FIG. 9 is a view schematically illustrating an example arrangement of gate electrodes and Schottky conductor layers in a semiconductor device according to a second alternative embodiment of the first embodiment; and

FIG. 10 is a view schematically illustrating an example planar shape of source regions, base contact regions, and field relaxation regions of a semiconductor device according to a comparative example.

### DETAILED DESCRIPTION

Embodiments of the present disclosure will now be described with reference to drawings. In the description of drawings, identical or similar components are indicated by an identical or similar sign, and redundant explanations will not be described. The drawings are schematic, and the relationship between thickness and plan dimension, the ratio of thicknesses of layers, or the like may differ from the actual ones. The dimensional relationships or ratios may differ between drawings. The embodiments described below are merely illustrative examples of devices or methods for embodying the technical ideas of the present disclosure, and the technical ideas of the disclosure do not specify the materials, shapes, structures, arrangements, or the like of components as follows.

In the present description, the “first main electrode region” means a semiconductor region that is one of the source region and the drain region in a field-effect transistor (FET) or a static induction transistor (SIT). In an insulated gate bipolar transistor (IGBT), the “first main electrode region” means a semiconductor region that is one of the emitter region and the collector region. In a static induction thyristor (SI thyristor) or a gate turn-off thyristor (GTO), the “first main electrode region” means a semiconductor region that is one of the anode region and the cathode region. The “second main electrode region” means a semiconductor region that is the other of the source region and the drain region in the FET or a SIT. In the IGBT, the “second main electrode region” means a region that is the other of the emitter region and the collector region. In the SI thyristor or the GTO, the “second main electrode region” means a semiconductor region that is the other of the anode region and the cathode region. As described above, when a “first main electrode region” is the source region, a “second main electrode region” means the drain region. When a “first main electrode region” is the emitter region, a “second main electrode region” means the collector region. When a “first main electrode region” is the anode region, a “second main electrode region” means the cathode region. By exchanging the bias relationship, the function of the “first main electrode region” is interchangeable with the function of the “second main electrode region” in an FET or the like. In the present description, a region simply called a “main electrode region” comprehensively means one of the first main electrode region and the second main electrode region.

In the following description, the definitions of directions such as up and down directions are merely for convenience of explanation and do not limit the technical ideas of the disclosure. For example, when an object is rotated by 90° and observed, the up and down directions are converted to left and right directions, and when an object is rotated by 180° and observed, the up and down directions are inverted, needless to say. A “top face” may also be read as a “front face”, and a “bottom face” may also be read as a “back face”.

In the following description, a case in which a first conductivity type is an n type and a second conductivity type is a p type will be described as an example. However, the relationship of the conductivity types may be inverted to set the first conductivity type to the p type and the second conductivity type to the n type. A semiconductor region denoted by “n” or “p” with “+” or “−” means that such a semiconductor region has a higher or lower impurity density than a semiconductor region denoted by “n” or “p” without “+” or “−”. It should be noted that a semiconductor region denoted by n and a semiconductor region denoted by the same n may not have exactly the same impurity density. Furthermore, in the following description, it is technically and logically obvious that a member or a region with the limitation of “first conductivity type” or “second conductivity type” means a member or a region made of a semiconductor material even if not specifically stated.

### First Embodiment

### Overview

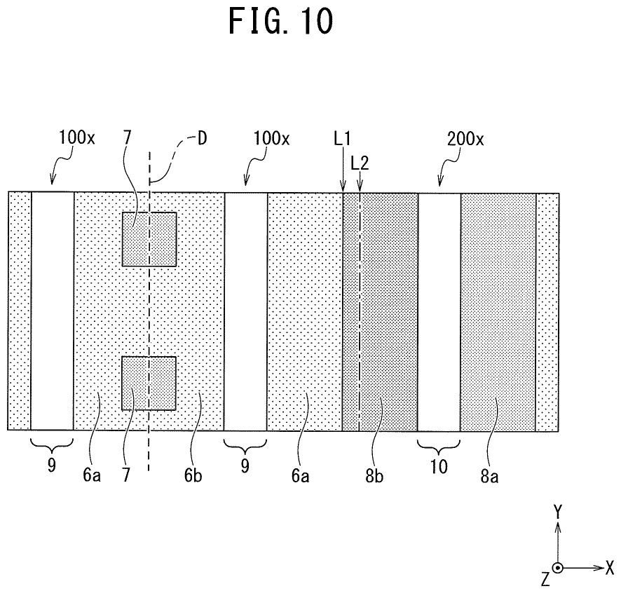

To a power semiconductor device including a transistor such as a MOSFET and a freewheeling diode, for example, a voltage of about several hundred volts is applied. When an electric current is passed through the transistor in such a power semiconductor device, a depletion layer generated between the n type source region of the transistor and the p type field relaxation region moves toward the diode. For example, as illustrated in a comparative example in FIG. 10, assume that a source region 6a of a transistor 100x and a field relaxation region 8b adjacent to a freewheeling diode 200x are in contact with each other on a straight boundary L1 in plan view. A depletion layer (not illustrated) is generated along the boundary L1. When an electric current is passed through the transistor in this condition, the boundary L1 moves toward the freewheeling diode 200x to a position indicated by sign L2. Accordingly, the depletion layer also moves to the position indicated by sign L2. The depletion layer moving toward the freewheeling diode 200x reduces the width of the field relaxation region 8b, and this may lower the breakdown resistance of the freewheeling diode 200x. Even if a source region 6a and a field relaxation region 8b were designed to have the same width, an electric current passing through the transistor would reduce the width of the field relaxation region 8b, and this could lower the breakdown resistance of the freewheeling diode 200x as described above. If the boundary L1 were a straight line, the transistor 100x would have a bilaterally asymmetric structure. This could lower the threshold voltage Vth, and contact variations could cause local current concentration, resulting in a high electric field. In addition, characteristics of the transistor 100x could vary, and this could affect the reliability.

### <Structure of Semiconductor Device>

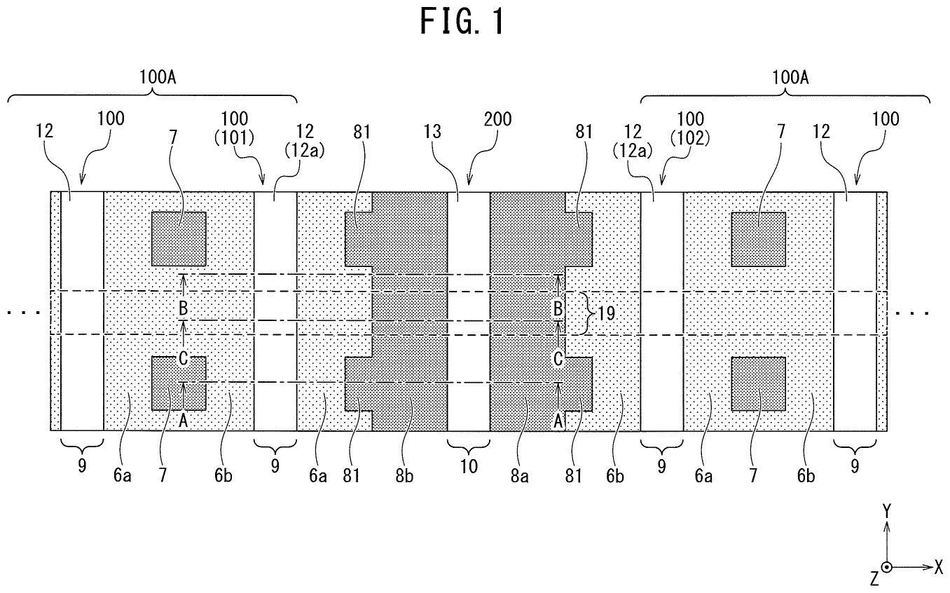

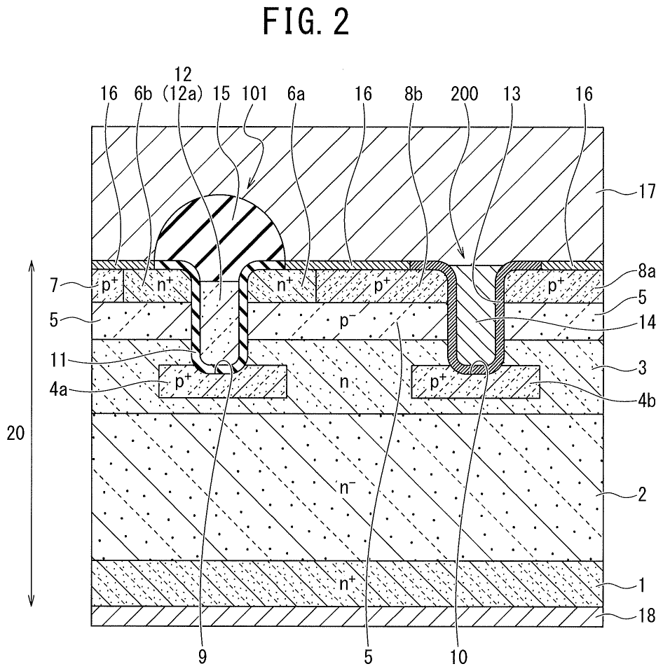

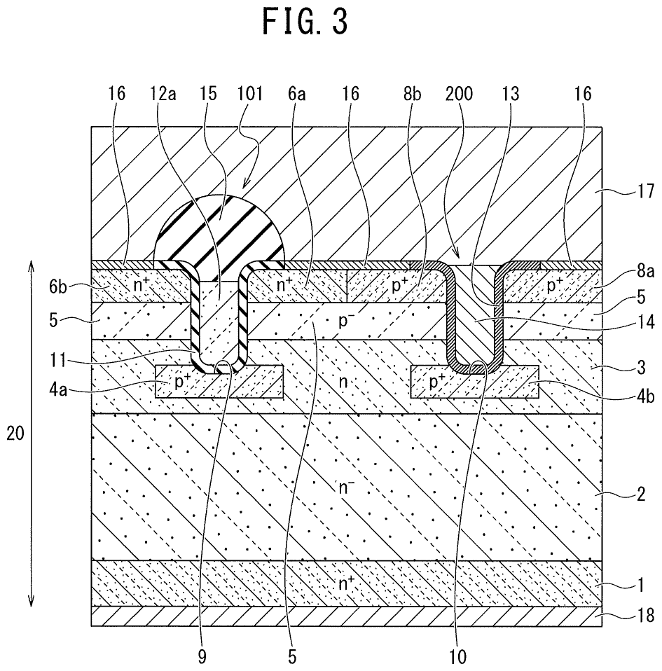

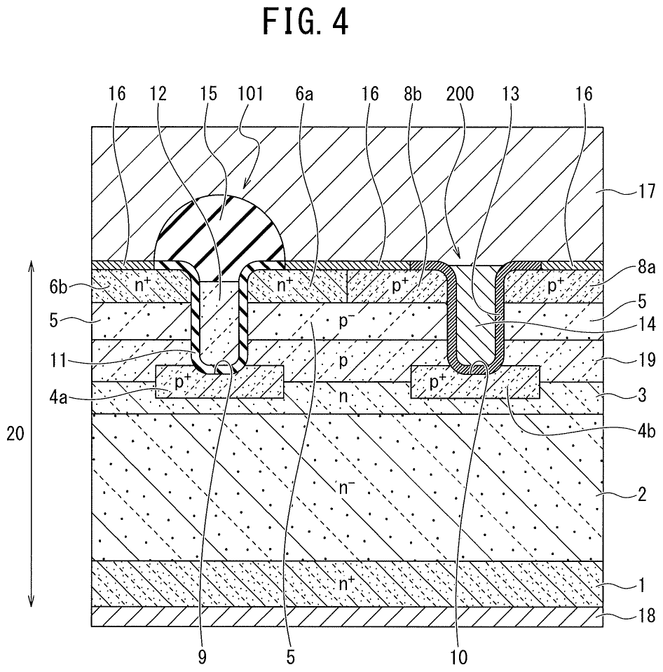

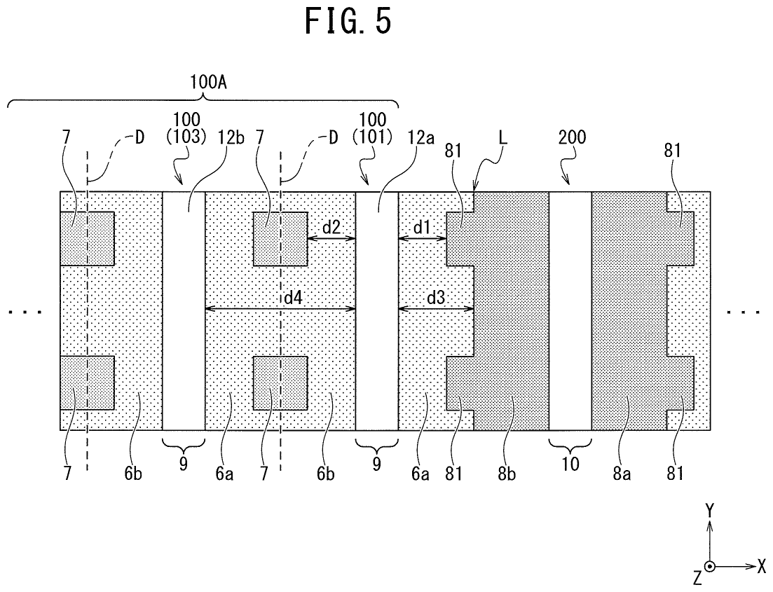

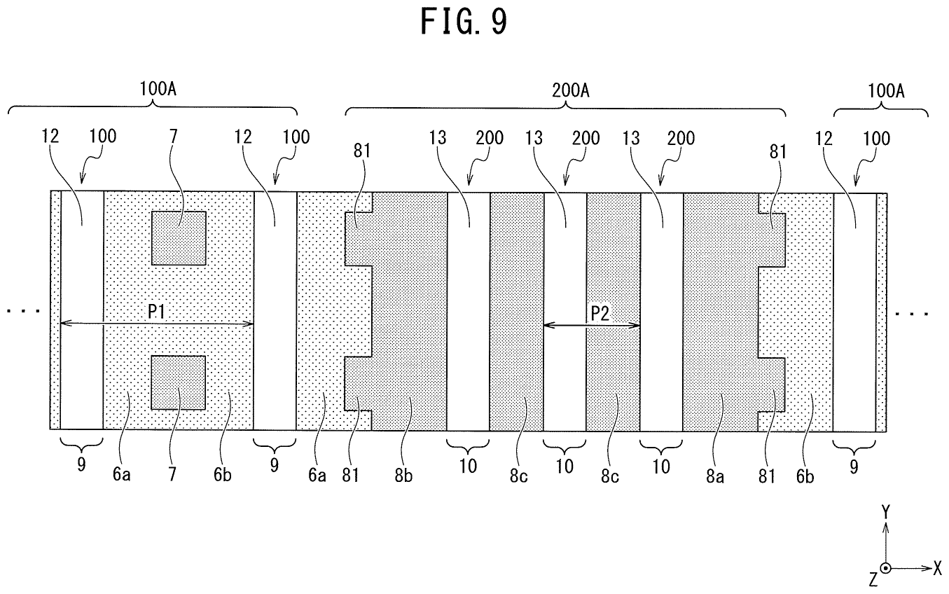

As a semiconductor device (semiconductor chip) according to a first embodiment, a trench gate MOSFET (metal-oxide-semiconductor field-effect transistor) will be described as an example. As illustrated in FIG. 1 to FIG. 4, the semiconductor device according to the first embodiment includes a transistor 100 as the active element and a diode 200 as the freewheeling diode (FWD). The freewheeling diode is provided to discharge surge currents generated when the transistor 100 turns on or off, for example. The transistor 100 is, for example, a MOSFET. The diode 200 is, for example, a Schottky barrier diode (SBD) but may be a PiN diode. FIG. 2 illustrates a vertical cross section taken along line A-A in FIG. 1. FIG. 3 illustrates a vertical cross section taken along line B-B in FIG. 1. FIG. 4 illustrates a vertical cross section taken along line C-C in FIG. 1. In FIG. 1, to clearly explain the positional relationship, the plan positions of gate electrodes 12 buried in gate trenches 9 and a Schottky conductor layer 13 provided along the side face and the bottom face of a diode trench 10 are also illustrated. The same applies to FIG. 5 and FIG. 9.

As illustrated in FIG. 1, the semiconductor device according to the first embodiment includes transistors 100 and a diode 200 that is adjacent to the transistors 100 in the X direction in plan view. A plurality (two or more) of the transistors 100 are provided adjacent to each other in the X direction to form a group 100A. A plurality of the groups 100A are provided, and between the adjacent groups 100A, one diode 200 is provided. The groups 100A and the diodes 200 are alternately provided multiple times in the X direction to form an array of, for example, a group 100A, a diode 200, a group 100A, and a diode 200. In the semiconductor region between the transistors 100 and the diode 200, field relaxation regions 8a, 8b are provided. By arranging a plurality of the transistors 100 to form a multichannel structure, the semiconductor device according to the first embodiment may constitute a power semiconductor device (power device) through which a large current passes. The transistor 100 placed adjacent to the left side of the diode 200 on the figure plane is called a transistor 101 for the sake of distinction from other transistors. The transistor 100 placed adjacent to the right side of the diode 200 on the figure plane is called a transistor 102 for the sake of distinction from other transistors. When not distinguished from other transistors, transistors 101, 102 are simply called transistors 100. Of a plurality of the transistors included in a single group 100A, a transistor 101 is the transistor located on the rightmost side (right end) in the X direction, and is adjacent to the left side of the diode 200. Of a plurality of the transistors included in a single group 100A, a transistor 102 is the transistor located on the leftmost side (left end) in the X direction, and is adjacent to the right side of the diode 200. The transistor 102 is a mirror image of the transistor 101 around the diode 200 at the center. In the present embodiment, therefore, the structure of the technology will be described by using the transistor 101 as an example.

As illustrated in FIG. 2, the insulated gate semiconductor device according to the first embodiment includes a semiconductor substrate 20. The semiconductor substrate 20 is formed of a SiC semiconductor substrate containing silicon carbide (SiC). When the semiconductor substrate 20 is formed of the SiC semiconductor substrate, the insulated gate semiconductor device according to the first embodiment is a SiC semiconductor device. The semiconductor substrate 20 is not limited to SiC substrates, and may be a semiconductor substrate containing a wide band gap semiconductor such as gallium nitride (GaN), gallium oxide (Ga₂O₃), diamond (C), or aluminum nitride (AN), or may be a silicon (Si) semiconductor substrate.

The semiconductor substrate 20 includes a first conductivity type (n-type) drift layer 2. On the top face of the drift layer 2, a first conductivity type (n type) current spreading layer (CSL) 3 having a higher impurity concentration than the drift layer 2 is selectively provided. The bottom face of the current spreading layer 3 is in contact with the top face of the drift layer 2. The current spreading layer 3 is not necessarily provided. When no current spreading layer 3 is provided, the drift layer 2 may be provided to extend to the region of the current spreading layer 3. On the top face of the current spreading layer 3, a second conductivity type (p-type) base region 5 is provided. The bottom face of the base region 5 is in contact with the top face of the current spreading layer 3. When no current spreading layer 3 is provided, the bottom face of the base region 5 is in contact with the top face of the drift layer 2.

On the top face of the base region 5, first main electrode regions (source regions) 6a, 6b and a base contact region 7 of the transistor 101 are provided. The source regions 6a, 6b are first conductivity type (n⁺ type) semiconductor regions having a higher impurity concentration than the drift layer 2. The base contact region 7 is a second conductivity type (p⁺ type) semiconductor region having a higher impurity concentration than the base region 5. The bottom faces of the source regions 6a, 6b and the bottom face of the base contact region 7 are in contact with the top face of the base region 5. On the top face of the base region 5, field relaxation regions 8a, 8b are provided. The field relaxation regions 8a, 8b are second conductivity type (p⁺ type) semiconductor regions having a higher impurity concentration than the base region 5 and are a breakdown voltage structure such as a guard ring (a field limiting ring). The bottom faces of the field relaxation regions 8a, 8b are in contact with the top face of the base region 5.

On the top face side of the semiconductor substrate 20, a trench (gate trench) 9 of the transistor 101 is provided. The gate trench 9 penetrates the source regions 6a, 6b and the base region 5 from the top faces of the source regions 6a, 6b in the normal direction (depth direction) of the top faces of the source regions 6a, 6b. On the right side of the gate trench 9, the source region 6a is located, and on the left side, the source region 6b and the base contact region 7 are located. In the present embodiment, the direction connecting the right side and the left side of the gate trench 9 is defined as the X direction. Between the base contact region 7 and the gate trench 9, the source region 6b is interposed, and the side face of the source region 6b is in contact with the side face of the base contact region 7. The right side face of the gate trench 9 is in contact with the source region 6a, the base region 5, and the current spreading layer 3. The left side face of the gate trench 9 is in contact with the source region 6b, the base region 5, and the current spreading layer 3. On the bottom of the gate trench 9, a gate bottom protection region 4a is provided. The gate bottom protection region 4a is a second conductivity type (p⁺ type) semiconductor region having a higher impurity concentration than the base region 5 and is provided in the current spreading layer 3. The gate bottom protection region 4a has a plane pattern of a stripe extending in the back direction and the front direction on the plane of FIG. 2. When no current spreading layer 3 is provided, the side face of the gate trench 9 may be in contact with the drift layer 2 instead of the current spreading layer 3. The gate bottom protection region 4a may be provided in the drift layer 2. The gate trench 9 is not limited to the plane pattern of the extending stripe illustrated in FIG. 1 but may have a plane pattern of dots (not illustrated).

As illustrated in FIG. 2, a gate insulating film 11 is provided so as to cover the bottom face (lower face) and the side face of the gate trench 9. As the gate insulating film 11, for example, a single layer film of any of a silicon dioxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (Zro₂) film, a tantalum oxide (Ta₂O₅) film, and a bismuth oxide (Bi₂O₃) film or a stacked-layer film prepared by stacking a plurality of such films may be used.

In the gate trench 9, a gate electrode 12 is buried on the gate insulating film 11. The gate insulating film 11 and the gate electrode 12 constitute an insulated gate electrode structure (11, 12). In other words, the transistor 100 is a trench transistor. The group 100A illustrated in FIG. 1 is a group of a plurality of gate electrodes 12 arranged adjacent to each other in the X direction. Of the plurality of gate electrodes 12 included in a single group 100A, the gate electrode 12 adjacent to the diode 200, or the gate electrode 12 located on the outermost side in the X direction is called a gate electrode 12a for the sake of distinction from other gate electrodes 12. The gate electrode 12a is a first gate electrode. When not distinguished from other gate electrodes 12, the gate electrode 12a is simply called a gate electrode 12. As the material of the gate electrode 12, for example, a polysilicon film (doped polysilicon film) containing impurities such as phosphorus (P) and boron (B) at a high impurity concentration may be used.

As illustrated in FIG. 2, on the top face of the insulated gate electrode structure (11, 12), an interlayer insulating film 15 is selectively provided. The interlayer insulating film 15, for example, includes a single layer film such as a silicon oxide film containing boron (B) and phosphorus (P) (BPSG film), a silicon oxide film containing phosphorus (P) (PSG film), a non-doped silicon oxide film containing neither phosphorus (P) nor boron (B) and called “NSG”, a silicon oxide film containing boron (B) (BSG film), and a silicon nitride film (Si₃N₄ film) or a stacked-layer film prepared by stacking a plurality of such films.

On the top face side of the semiconductor substrate 20, a trench (diode trench) 10 of the diode 200 is provided apart from the gate trench 9 of the transistor 101. As illustrated in FIG. 1, the diode 200 is provided parallel to the gate trench 9. As illustrated in FIG. 2, the diode trench 10 penetrates the field relaxation regions 8a, 8b and the base region 5 from the top faces of the field relaxation regions 8a, 8b in the normal direction (depth direction) of the top faces of the field relaxation regions 8a, 8b. On the right side of the diode trench 10, the field relaxation region 8a is located, and on the left side, the field relaxation region 8b is located. As illustrated in FIG. 1, the right side face of the field relaxation region 8a is in contact with the left side face of the source region 6b. The left side face of the field relaxation region 8b is in contact with the right side face of the source region 6a. The field relaxation regions 8a, 8b are provided to maintain the withstand voltage characteristics of the diode 200 against electric fields. As illustrated in FIG. 2, the right side face of the diode trench 10 is in contact with the field relaxation region 8a, the base region 5, and the current spreading layer 3. The left side face of the diode trench 10 is in contact with the field relaxation region 8b, the base region 5, and the current spreading layer 3. On the bottom of the diode trench 10, a trench bottom protection region 4b is provided. The trench bottom protection region 4b is a second conductivity type (p⁺ type) semiconductor region having a higher impurity concentration than the base region 5 and is provided in the current spreading layer 3. The trench bottom protection region 4b has a plane pattern of a stripe extending in the back direction and the front direction on the plane of FIG. 2. When no current spreading layer 3 is provided, the side face of the diode trench 10 may be in contact with the drift layer 2 instead of the current spreading layer 3. The trench bottom protection region 4b may be provided in the drift layer 2.

A Schottky conductor layer 13 is provided so as to cover the bottom face (lower face) and the side face of the diode trench 10. The Schottky conductor layer 13 consists of or contains any of titanium (Ti), molybdenum (Mo), tungsten (W), and nickel (Ni), for example. The Schottky conductor layer 13 may be a single layer film of any of the above materials or a stacked-layer film of a plurality of such materials. In the diode trench 10, an electrode 14 is buried on the Schottky conductor layer 13. The electrode 14 is, for example, made of a metal material. The electrode 14 consists of or contains tungsten (W) or aluminum (Al), for example. The Schottky conductor layer 13 is joined to the current spreading layer 3 in the Schottky manner. When no current spreading layer 3 is provided, the Schottky conductor layer 13 is joined to the drift layer 2 in the Schottky manner. As described above, the diode 200 is a trench Schottky barrier diode.

The semiconductor device according to the first embodiment has a semiconductor region 19 in the plan position illustrated in FIG. 1. As illustrated in FIG. 4, the semiconductor region 19 is a second conductivity type (p type) semiconductor region provided on the lower side of the base region 5 and having a higher impurity concentration than the base region 5. As illustrated in FIG. 1, the longitudinal direction in plan view of the semiconductor region 19 extends in the X direction. More specifically, the longitudinal direction in plan view of the semiconductor region 19 extends over a plurality of the transistors 100 and a plurality of the diodes 200. The dimension of the semiconductor region 19 in the short direction in plan view is smaller than the distance between projections 81 described later, for example. Hence, the Schottky region of the diode 200 is not completely buried. The longitudinal direction in plan view of the semiconductor region 19 may be provided only across the transistors 100. As illustrated in FIG. 4, the top face of the semiconductor region 19 is in contact with the bottom face of the base region 5. The lower side of the semiconductor region 19 is in contact with the gate bottom protection region 4a and the trench bottom protection region 4b. The semiconductor region 19 functions to connect the gate bottom protection region 4a and the trench bottom protection region 4b to the base region 5. The bottom face of the semiconductor region 19 is located shallower than the bottom faces of the gate bottom protection region 4a and the trench bottom protection region 4b. Providing the semiconductor region 19 enables an improvement in the breakdown resistance of the transistor 100. Providing the semiconductor region 19 makes it easier to prepare a transistor 101 in which a diode is adjusted (connected) to the structure of the transistor 101.

As illustrated in FIG. 2, a first main electrode (source electrode) 17 is provided so as to cover the top faces of the source regions 6a, 6b, the field relaxation regions 8a, 8b, and the electrode 14. The bottom face of the source electrode 17 is in contact with the top faces of the source regions 6a, 6b, the base contact region 7, and the field relaxation regions 8a, 8b, and the electrode 14 and is electrically conductive. The source electrode 17 is provided separately from a gate wiring electrode (not illustrated) electrically connected to the gate electrode 12. The source electrode 17 has a barrier metal layer 16 on the bottom face. The barrier metal layer 16 is in contact with the top face of the semiconductor substrate 20. The barrier metal layer 16 is selectively provided, for example, at positions overlapping with the source regions 6a, 6b and the field relaxation regions 8a, 8b. The barrier metal layer 16 includes a metal such as titanium nitride (TiN), titanium (Ti), and a TiN/Ti multilayer structure in which Ti is the lower layer. The source electrode 17 other than the barrier metal layer 16, for example, includes a metal such as aluminum (Al), aluminum-silicon (Al—Si), aluminum-copper (Al—Cu), and copper (Cu). The above electrode 14 and the source electrode 17 may be integrally formed from the same material.

On the bottom face of the drift layer 2, a first conductivity type (n⁺ type) second main electrode region (drain region) 1 having a higher impurity concentration than the drift layer 2 is provided. The drain region 1 is formed of a semiconductor substrate (SiC substrate) formed of SiC. Between the drift layer 2 and the drain region 1, a dislocation conversion layer or a recombination promotion layer that is an n type buffer layer having a higher impurity concentration than the drift layer 2 and having a lower impurity concentration than the drain region 1 may be provided.

On the bottom face of the drain region 1, a second main electrode (drain electrode) 18 is provided. As the drain electrode 18, for example, a single layer film of gold (Au) or a metal film in which titanium (Ti), nickel (Ni), and Au are stacked in this order from the drain region 1 may be used, and a metal film such as a molybdenum (Mo) film and a tungsten (W) film may be further stacked as the lowermost layer. Between the drain region 1 and the drain electrode 18, a drain contact layer such as a nickel silicide (NiSiₓ) film may be provided for ohmic contact. An electrode simply called a “main electrode” comprehensively means one of the first main electrode (source electrode) 17 and the second main electrode (drain electrode) 18.

The structures of the source regions 6a, 6b, the base contact region 7, and the field relaxation regions 8a, 8b will next be described in detail with reference to FIG. 5. In plan view, the field relaxation region 8a is a mirror image of the field relaxation region 8b around the diode trench 10 at the center. In the present embodiment, only the structure of the field relaxation region 8b of the field relaxation regions 8a, 8b will be described.

The boundary D between transistors 100 included in a group 100A is roughly indicated by a dot-dash line. The boundary D is not actually visible. The transistor 100 provided adjacent to the left side of the transistor 101 is called a transistor 103 for the sake of distinction from other transistors. When not distinguished from other transistors, the transistor 103 is simply called a transistor 100. The gate electrode 12 of the transistor 103 provided adjacent to the left side of the gate electrode 12a is called a gate electrode 12b for the sake of distinction from other gate electrodes 12. When not distinguished from other gate electrodes 12, the gate electrode 12b is simply called a gate electrode 12. The source region 6b on the left side of the gate electrode 12a is provided integrally with the source region 6a on the right side of the gate electrode 12b in a continuous manner across the boundary D. Between the gate electrode 12a and the gate electrode 12b, a plurality of island-shaped base contact regions 7 are arranged in the Y direction. The base contact regions 7 are located at an equal distance from the gate electrodes 12a, 12b and are shared by the transistor 101 and the transistor 103. Between adjacent gate electrodes 12, base contact regions 7 are similarly provided.

The field relaxation region 8b has portions facing the base contact regions 7 and portions not facing the base contact regions in the Y direction. Of the field relaxation region 8b, the portions facing the base contact regions 7 protrude toward the gate electrode 12a in plan view, relative to the portions not facing the base contact regions. The protruding portion is called a projection 81. The dimension of the projection 81 in the Y direction is designed to be almost equal to the dimension of the base contact region 7 in the Y direction. The distance between the projections 81 adjacent in the Y direction is designed to be almost equal to the distance between the base contact regions 7 adjacent in the Y direction. FIG. 5 illustrates a boundary L in plan view between the source region 6a on the right side of the gate electrode 12a and the field relaxation region 8b. The boundary L is nonlinear and is curved in a rectangular wave pattern along the projections 81. A depletion layer (not illustrated) is generated along the boundary L. When the distance between the portion with the projection 81 in the field relaxation region 8b and the gate electrode 12a is d1, and the distance between the portion without the projection 81 in the field relaxation region 8b and the gate electrode 12a is d3, d1 is smaller than d3 (d1<d3). Providing the projections 81 partly reduces the distance between the field relaxation region 8b and the gate electrode 12a. This partly shifts the depletion layer generated along the boundary L closer to the transistor 101 and partly shifts the depletion layer away from the diode 200. Accordingly, even when a current is passed through the transistor 100, the depletion layer is prevented from approaching the diode 200 too closely, and the decrease in breakdown resistance of the diode 200 is suppressed.

The reason why the boundary between the source region 6a on the right side of the gate electrode 12a and the field relaxation region 8b is not uniformly shifted closer to the gate electrode 12a will next be described. When the distance between the base contact region 7 and the gate electrode 12a is d2, and the distance between the adjacent gate electrodes 12 is d4, the distance d1 satisfies the following expression (1), and the distance d3 satisfies the following expression (2).

$$d 2 \times 0.9 \leq d 1 \leq d 2 \times 1.1 \qquad ( 1 )$$

$$( d 4 / 2 ) \times 0.9 \leq d 3 \leq ( d 4 / 2 ) \times 1.1 \qquad ( 2 )$$

By setting d1 and d3 to the values as described above, the source region 6a on the right side of the gate electrode 12a becomes a mirror image of the source region 6b on the left side around the gate electrode 12a at the center as illustrated in FIG. 2, FIG. 3, and FIG. 5. The source region 6a on the right side of the gate electrode 12a has an identical or similar shape to the source region 6a on the right side of the gate electrode 12b. By designing the source region 6a on the right side of the gate electrode 12a to have the shape as described above, the transistor functions evenly on the right side and the left side of the gate electrode 12a, enabling balanced operation. By providing the source regions 6a, 6b as evenly as possible on the right and left sides of the gate electrode 12a, an electric field is unlikely to concentrate to the boundary L between the source region 6a and the field relaxation region 8b. This can further suppress the decrease in breakdown resistance of the diode 200. This can also suppress the decrease in breakdown resistance of the transistor 101. The above-mentioned d1, d2, d3, and d4 are dimensions when no bias voltage is applied and no current is passed through the transistor 100.

### Main Effect of First Embodiment

In the semiconductor device according to the first embodiment, portions of the field relaxation region 8b facing the base contact regions 7 protrude toward the gate electrode 12a in plan view. More specifically, the portions of the field relaxation region 8b facing the base contact regions 7 protrude toward the gate electrode 12a in plan view, relative to the portions not facing the base contact regions 7. The voltage increases at a pn junction directly below the depletion layer. With the structure of the field relaxation region 8b as described above, the region where the voltage increases is shifted toward the transistor 101. This can reduce the voltage load on the diode 200 to suppress the decrease in breakdown resistance of the diode 200. By optimizing the structure of the connection portion between the field relaxation region 8b and the source region 6a, a highly reliable device maintaining a high breakdown voltage can be produced.

In the semiconductor device according to the first embodiment, the distance d1 and the distance d3 illustrated in FIG. 5 are set to values defined by the expression (1) and the expression (2). The boundary L is provided such that the field relaxation region 8b is not uniformly expanded toward the gate electrode 12a but the source region 6a on the right side of the gate electrode 12a is a mirror image of the source region 6b on the left side. Accordingly, the transistor functions evenly on the left and right sides of the gate electrode 12a, and this suppresses the tendency of electric fields to concentrate on one of the left and right sides of the gate electrode 12a. This can improve the breakdown resistance of the diode 200 without significantly changing the breakdown resistance of the transistor 101.

### First Alternative Embodiment of First Embodiment

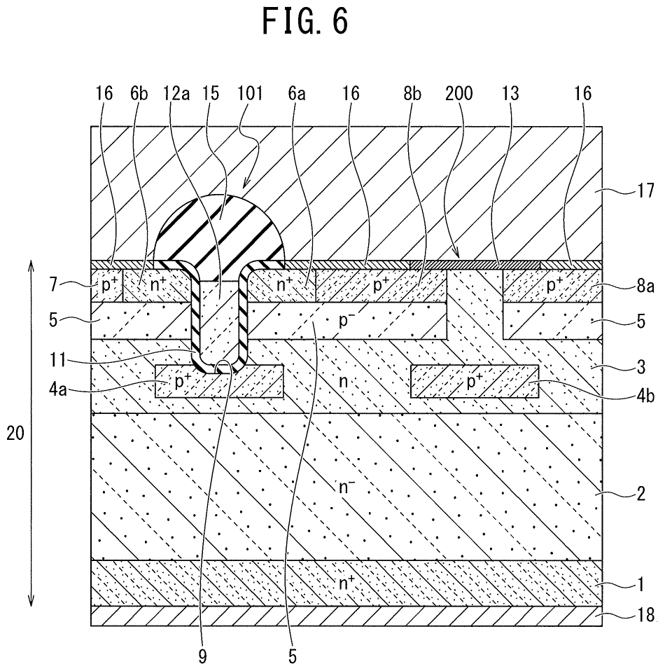

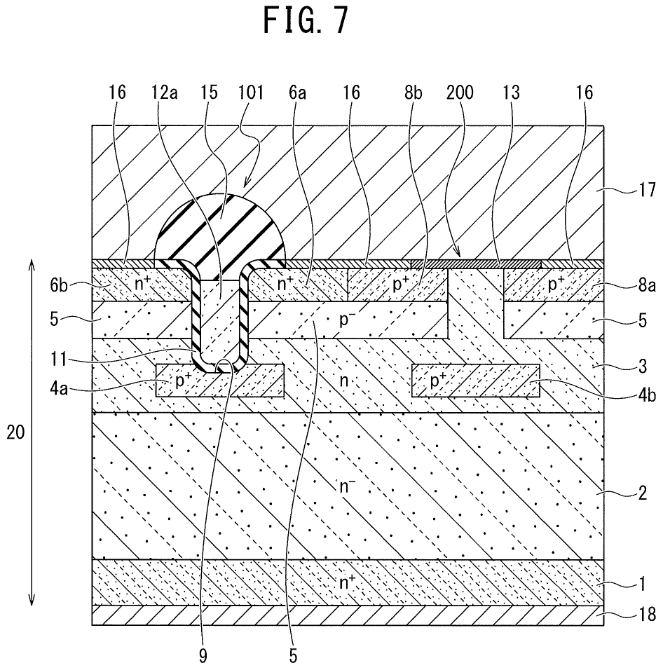

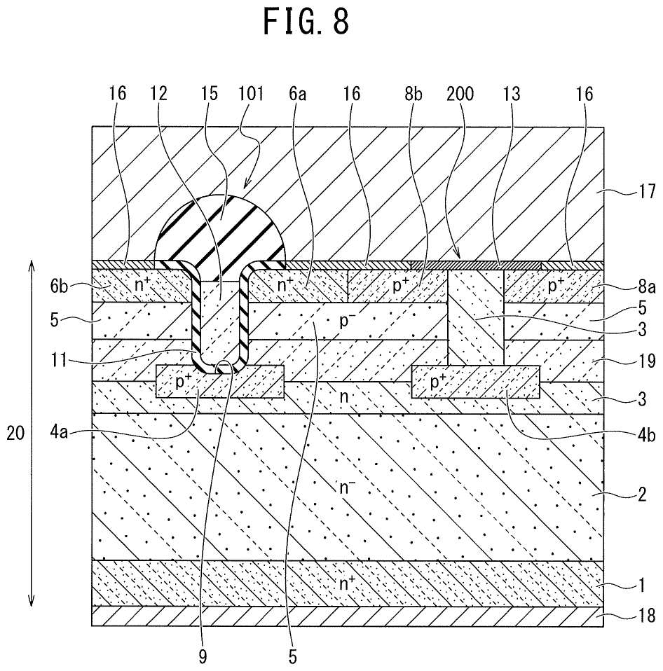

A semiconductor device according to a first alternative embodiment of the first embodiment differs from the above semiconductor device according to the first embodiment in that the diode 200 is a planar Schottky barrier diode as illustrated in FIG. 6, FIG. 7, and FIG. 8. The other structure of the semiconductor device according to the first alternative embodiment of the first embodiment is the same as that of the semiconductor device according to the first embodiment, and redundant explanations will not be described. FIG. 6 is a longitudinal sectional view of a portion with a projection 81 of a field relaxation region 8b, in the X direction. FIG. 7 is a longitudinal sectional view of a portion without the projection 81 of the field relaxation region 8b, in the X direction. FIG. 8 is a longitudinal sectional view of a portion with a semiconductor region 19 in the X direction. Even in the alternative embodiment, the planar shapes of a source region 6a, a field relaxation region 8b, and a base contact region 7 are the same as in FIG. 1. As illustrated in FIG. 6, FIG. 7, and FIG. 8, no diode trench 10 is provided in a semiconductor substrate 20. A Schottky conductor layer 13 is planar and has a bottom face joined to a current spreading layer 3 in the Schottky manner. When no current spreading layer 3 is provided, the Schottky conductor layer 13 is joined to a drift layer 2 in the Schottky manner. The semiconductor device according to the first alternative embodiment of the first embodiment also provides substantially the same effect as the above semiconductor device according to the first embodiment.

### Second Alternative Embodiment of First Embodiment

In the semiconductor device according to the first embodiment, a single Schottky conductor layer 13 is provided between the groups 100A as illustrated in FIG. 1, but the present technology is not limited to this structure. In a semiconductor device according to a second alternative embodiment of the first embodiment, a plurality of Schottky conductor layers 13 are provided between groups 100A as illustrated in FIG. 9. A plurality of (two or more) Schottky conductor layers 13 of diodes 200 are arranged adjacent to each other in the X direction to form a group 200A. The groups 100A and the groups 200A are alternately provided multiple times in the X direction to form an array of, for example, a group 100A, a group 200A, a group 100A, and a group 200A. The other structure of the semiconductor device according to the second alternative embodiment of the first embodiment is the same as that of the semiconductor device according to the first embodiment, and redundant explanations will not be described.

When the Vf (forward voltage generated between an anode and a cathode of the Schottky barrier diode) is intended to be reduced, a plurality of diodes 200 (Schottky conductor layers 13) may be arranged in the X direction. In order to increase the number of Schottky conductor layers 13 included in a single group 200A, the arrangement pitch P2 of Schottky conductor layers 13 may be reduced. For example, the arrangement pitch P2 of Schottky conductor layers 13 may be smaller than the arrangement pitch P1 of gate electrodes 12. The number of Schottky conductor layers 13 provided between groups 100A may be smaller than the number of gate electrodes 12 included in a single group 100A. Between the Schottky conductor layers 13, a field relaxation region 8c is provided. The diode 200 illustrated in FIG. 9 may be a trench diode or a planar diode. With the semiconductor device according to the second alternative embodiment of the first embodiment, the forward voltage of the diode 200 can be reduced because a plurality of diodes 200 are arranged.

### Other Embodiments

The first embodiment and the alternative embodiments thereof have been described as above, but the description and drawings constituting a part of the disclosure should not be understood to limit the disclosure. From the disclosure, various alternative embodiments, examples, and operational technologies will be apparent to a person skilled in the art.

For example, as the semiconductor devices according to the first embodiment and the alternative embodiments thereof, a MOSFET is exemplified, but the present disclosure is also applicable to an insulated gate bipolar transistor (IGBT) having a structure in which a p⁺ type collector region is provided in place of the n⁺ type drain region 1. In addition to the IGBT alone, the present disclosure is further applicable to a reverse conduction IGBT (RC-IGBT) or a reverse blocking insulated gate bipolar transistor (RB-IGBT). In the above embodiments, the transistor 100 is a trench transistor but may be a planar transistor.

The configurations disclosed in the first embodiment and the alternative embodiments thereof may be appropriately combined to the extent that no inconsistency arises. Needless to say, the disclosure includes various embodiments and the like not described in the present description. The technical scope of the present disclosure is therefore defined only by the invention specifying matters according to the claims and reasonable from the above description.

1. A semiconductor device comprising:
a semiconductor substrate;
a transistor provided in the semiconductor substrate and having a gate electrode, a first conductivity type main electrode region provided on one side of the gate electrode, and a second conductivity type base contact region provided on another side of the gate electrode;
a diode provided in the semiconductor substrate and adjacent to the transistor on the one side of the gate electrode; and
a second conductivity type field relaxation region provided between the transistor and the diode in the semiconductor substrate and having a side face in contact with the main electrode region, wherein
a portion of the field relaxation region facing the base contact region protrudes toward the gate electrode in plan view.

2. The semiconductor device according to claim 1, wherein
when a direction connecting the one side and the other side of the gate electrode is X direction, and a direction perpendicular to the X direction in plan view is Y direction,
a plurality of the base contact regions having an island shape are arranged in the Y direction,
the main electrode region is also provided on the other side of the gate electrode and is in contact with the base contact regions, and
the portion of the field relaxation region facing the base contact region protrudes toward the gate electrode in plan view, relative to a portion not facing the base contact region.

3. The semiconductor device according to claim 2, wherein
the semiconductor device includes a plurality of groups, the group includes a plurality of the gate electrodes arranged adjacent in the X direction,
the diode is provided between the adjacent groups,
d2×0.9≤d1≤d2×1.1 is satisfied, where d1 is a distance between a first gate electrode and the protruding portion, the first gate electrode is a gate electrode of the plurality of gate electrodes included in the group and is adjacent to the diode, and d2 is a distance between the first gate electrode and the base contact region, and
(d4/2)×0.9≤d3≤(d4/2)×1.1 is satisfied, where d3 is a distance between the first gate electrode and the portion not facing the base contact region, and d4 is a distance between the adjacent gate electrodes.

4. The semiconductor device according to claim 1, wherein the diode is a Schottky barrier diode having a Schottky conductor layer in contact with the semiconductor substrate.

5. The semiconductor device according to claim 4, wherein the diode is a planar Schottky barrier diode or a trench Schottky barrier diode.

6. The semiconductor device according to claim 4, wherein the semiconductor device includes a main electrode, and the main electrode is in contact with a top face of the main electrode region and with a top face of the base contact region and is electrically connected to the Schottky conductor layer.

7. The semiconductor device according to claim 4, wherein
when a direction connecting the one side and the other side of the gate electrode is X direction, and a direction perpendicular to the X direction in plan view is Y direction,
the semiconductor device includes a plurality of groups, the group includes a plurality of the gate electrodes arranged adjacent in the X direction, and
a plurality of the Schottky conductor layers are arranged adjacent in the X direction between the adjacent groups.

8. The semiconductor device according to claim 7, wherein an arrangement pitch of the adjacent Schottky conductor layers is smaller than an arrangement pitch of the adjacent gate electrodes.

9. The semiconductor device according to claim 4, wherein
when a direction connecting the one side and the other side of the gate electrode is X direction, and a direction perpendicular to the X direction in plan view is Y direction,
the semiconductor device includes a plurality of groups, the group includes a plurality of the gate electrodes arranged adjacent in the X direction,
the Schottky conductor layer is provided between the adjacent groups or a plurality of the Schottky conductor layers are arranged adjacent in the X direction between the adjacent groups, and
the number of the Schottky conductor layers arranged between the groups is smaller than the number of the gate electrodes included in the group.

10. The semiconductor device according to claim 1, wherein
when a direction connecting the one side and the other side of the gate electrode is X direction, and a direction perpendicular to the X direction in plan view is Y direction,
the semiconductor device includes a second conductivity type semiconductor region, the second conductivity type semiconductor region is provided in contact with a bottom face of a base region of the transistor, and a longitudinal direction in plan view of the second conductivity type semiconductor region extends in the X direction.

11. The semiconductor device according to claim 1, wherein the semiconductor substrate is a silicon carbide semiconductor substrate.
